(19) United States
(12) Patent Application Publication
(10) Pub. No.: US 2024/0130096 A1
(43) Pub. Date: Apr. 18, 2024

(54) Shielding Element for Electronic Components

(71) Applicant: Aptiv Technologies AG, Schaffhausen (CH)

(72) Inventors: Armin Talai, Nürnberg (DE); Roberto Leonardi, Nürnberg (DE)

(21) Appl. No.: 18/486,231

(22) Filed: Oct. 13, 2023

(30) Foreign Application Priority Data
Oct. 13, 2022 (EP) 22201228

(51) Int. Cl. H05K 9/00; G01S 7/02

(52) U.S. Cl. CPC H05K 9/0056; G01S 7/023; H05K 9/0062; H01L 23/552

(57) ABSTRACT

A shielding element at least partially shields electromagnetic energy radiating from an electronic component. The shielding element includes an inner wall adapted to face the electronic component when assembled. The inner wall includes a material configured to at least partially reflect the electromagnetic energy radiating from the electronic component. The inner wall includes a structure adapted to interfere with at least one of the radiated or reflected electromagnetic energy.

### CROSS-REFERENCE TO RELATED APPLICATIONS

This application claims priority EP App. No. 22 201 228 filed Oct. 13, 2022, the entire disclosure of which is incorporated by reference.

### FIELD

The present disclosure relates to a shielding element for electronic components, such as electronic components of a radar system. The shielding element is adapted for at least partially shielding electromagnetic energy radiating from the electronic component. The present invention is further related to a respective system for a radar.

### BACKGROUND

Radar (radio detection and ranging) systems are presently abundantly available and are well known in the art. They are particularly useful for detecting and/or for tracking objects with the help of electromagnetic signals in the regime of radio waves. Radio waves are a type of electromagnetic radiation with the longest wavelengths in the electromagnetic spectrum (typically with frequencies of 300 Gigahertz, GHz, and below). Radar systems are applied in many industrial sectors, for instance in the automotive sector. A particular focus is applied to the microwave spectrum within the radio waves, including a type of electromagnetic radiation with a frequency between 300 MHz and 300 GHz. The frequency corresponds to a wavelength between 1 m and 1 mm. Term radio waves as used herein includes the regime of microwaves.

Radar systems typically have one or more electronic components which generate and/or receive radio frequency (RF) energy, such as an integrated circuit (IC) or more particularly a Monolithic Microwave Integrated circuit (MMIC). Radar systems may further have an antenna for transmitting and for receiving radio waves. This could also be the same antenna. Additionally, radar systems can have a receiver and processor to determine properties of the objects detected and/or tracked. Radio waves from the antenna are reflected from the objects to be detected and/or tracked and return to the receiver. Thereby, information about the objects can be retrieved.

For accurate detecting and/or tracking, the radio waves transmitted should not be distorted, interfered, or otherwise adversely affected. In particular, it is desired that electromagnetic interference noise is reduced.

The electronic components which generate and/or receive radio frequency can itself radiate electromagnetic energy into their environment. In this manner, the electronic components could influence the radio waves transmitted and/or received, which degrades the performance of the radar system.

Accordingly, there is a need to shield such electronic components from remaining parts of the (e.g. radar) system to increase the performance of the system. The means for shielding should be simple and cost-effective. In the prior art, attempts have been made to address this need.

For instance, electromagnetic interference (EMI) shields are known. EMI shields may surround or enclose an IC, such as an MMIC of a radar system. However, these known EMI shields typically include conductive material, such as metal. This causes a high reflectivity, leading to complex scattering scenarios within the EMI shield. Thus, reflection of electromagnetic energy is enhanced, which causes undesired coupling paths between transmission lines of the MMIC and remaining parts of the radar system, such as other transmission lines and or/antenna(s). Accordingly, transmitting and receiving of radio waves is interfered, as noise is created.

Other attempts have been made, which rely on more advanced material. For instance, materials are known that can absorb at least partially microwaves. Such materials may also act as thermal absorber materials at the same time. Particularly, materials are known that can at least partially absorb electromagnetic energy in the regime of radio frequency. However, such materials are expensive. Another drawback of these materials is that additional manufacturing steps are required for providing a shield that includes such a material. In addition, such materials may only be produced by specialized companies, which increases a dependency in the overall manufacturing chain.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In view of the foregoing, the prior art reveals a gap between existing solutions and the above need for shielding elements as posed above. In particular, existing shields fail to reduce noise, to improve the performance of the electronic system and to be cost-effective.

It is thus an object of the present invention to overcome some or all of the deficiencies of the prior art. In particular, it is an object of the invention to provide for an improved shielding element for electronic components, such as electronic components of a radar system. It is a further object of the invention to provide a simplified and cost-effective shielding element, which should be easy to manufacture. The shielding element should be provided with less complex parts and/or materials.

The above-mentioned objects are at least partially achieved by the subject-matter of the independent claims. Embodiments are subject of the dependent claims, and the skilled person finds hints for other suitable aspects of the present invention through the overall disclosure of the present application.

An aspect of the invention relates to a shielding element for electronic components, such as electronic components of a radar system, for at least partially shielding electromagnetic energy radiating from the electronic component, the shielding element including an inner wall, adapted to face the electronic component(s) when assembled, the inner wall including a material for at least partially reflecting the electromagnetic energy radiated by the electronic component(s). The inner wall includes a structure, adapted to interfere with the radiated and/or reflected electromagnetic energy.

This aspect has the advantage that radiated and/or reflected electromagnetic energy is interfered, and, thereby, impaired to be spread further. Thus, interference with (other) electronic components is substantially prevented. A potential noise generated at (other) electronic components can thus be reduced. If not appropriately shielded as done in conventional solutions, a complex scattering of electromagnetic energy can occur. This is usually expressed as a low isolation of, e.g. at most 34 dB at a frequency of 76.5 GHz, which is not sufficient.

The term “to interfere”, “interference” or the like as used herein may be understood in such a way that it (the structure) interposes in a way that substantially hinders and/or impedes something (the electromagnetic energy). Thus, it could mean as to come into collision, e.g. that the structure comes into collision with the electromagnetic energy. Accordingly, the term as used herein is not to be understood as in the term Electromagnetic Interference (EMI), as the latter term describes an adverse effect by way of the interference.

The term “when assembled” means that the shielding element is assembled together with the electronic component(s). Thus, the electronic component(s) are not necessarily included by the shielding element, but the shielding element should be suitable to be assembled with the electronic component(s). In one example, the assembling could mean that the shielding element at least partially houses the electronic component(s). In the assembled state, the shielding element houses the electronic component(s) completely.

The inner wall, adapted to face the electronic component(s), means that the inner wall could be located at an opposite side and/or a lateral side of the electronic component(s). The inner wall should at least be directed to the electronic component(s) in such a way that electromagnetic energy can be reflected.

As the inner wall includes a material for at least partially reflecting the electromagnetic energy radiated by the electronic component(s), the electromagnetic energy may be reflected. The material is not particularly limited. The material may include conductive material, which is relatively cost-effective and easy to procure. However, also more advanced materials that could already absorb part of electromagnetic energy may be encompassed.

The structure of the inner wall is not particularly limited and could be any, physical and/or visually recognizable, structure that can interfere with the radiated and/or reflected electromagnetic energy. Thus, the structure can interfere with both, i.e. the electromagnetic energy radiated from the electronic component (directly) and the electromagnetic energy reflected from the inner wall. The structure is provided with the intent to interfere with the electromagnetic energy. Thus, fixing means and/or shape variations necessary to a structural integrity of the shielding element are not usually encompassed by the structure.

The term “electronic components”/“electronic component(s)” as used herein may include any kind of electronic component, that is capable of at least partially radiating electromagnetic energy. One electronic component may already be sufficient to be referred to as electronic component(s). Thus, the invention already provides benefits if one electronic component is shielded. Accordingly, the term component(s) is used herein. An example of an electronic component is an integrated circuit (IC), such as a monolithic microwave integrated circuit (MMIC, as described further below). Other examples for an electronic component include one or more transmission lines, for instance transmission lines for conducting electromagnetic waves in a substantially contained manner.

The term “transmission line” could mean that the conductor in the line is long enough such that wave phenomena of the transmission should be taken into account. As an example, this could apply to a radio frequency range of about 20 MHz, in the order of magnitude of GHz, such as 1 GHz to about 300 GHz. This may be, because the wavelengths of the radio frequency are relatively short, which means that wave phenomena could arise over a short distance.

Further examples of electronic components may be: an electrical inverter, a battery, any electronic and/or electrical equipment or the like or any combinations thereof. The electronic components may be part of a system for a radar and/or used in the automotive sector.

The shielding element described herein, if used in a system for a radar, particularly improves the accuracy and performance of the radar in a cost-effective manner.

In the shielding element as described herein, the structure covers at least 10%, at least 20%, at least 30%, at least 40%, or at least 50% of a surface of the inner wall.

The structure covers at least a certain percentage of a surface of the inner wall. This means that, if e.g. the structure includes any structural elements, the surfaces of these structural elements would not additionally count to the surface of the inner wall. Thereby, the surface of the inner wall could be regarded as the surface of the inner wall where there is substantially no structure (as for instance in the prior art).

The inventors found that a minimal surface of the inner wall should be covered by the structure as this improves interference with the radiated and/or reflected electromagnetic energy. It was found that after a sufficient surface was covered by the structure, increasing the covering of the surface of the inner wall did not necessarily further improve the isolation and further reduce of noise within the shielding element. Thus, the inventors found that an optimum balance should be struck for covering the surface of the inner wall.

In the shielding element as described herein, the structure includes one or more elongated protrusions and/or recesses, the one or more elongated protrusions and/or recesses having the shape of ridges.

Protrusions may also be understood as a projection and/or something that protrudes from the structure. The one or more protrusions is/are directed in such a way that a distance to the electronic component is reduced, when assembled.

It is appreciated that the structure could also include recesses. A recess could also be understood as a valley. The one or more recesses is/are directed in such a way that a distance to the electronic component is increased, when assembled.

The shape of ridges may be understood in such a way that the one or more protrusions and/or recesses are at least partially tapered and/or conical. In one example, they could have the shape of ribs.

The one or more elongated protrusions and/or recesses have the advantage that interference with electromagnetic energy is further improved. In particular, an incoming electromagnetic energy path could be reflected by at least a part of the one or more elongated protrusions and/or recesses. The reflection could be in such a way that the electromagnetic energy path is substantially reversed. Thus, a scattering (or further transmission) in the incoming direction of the electromagnetic energy path is substantially prevented.

In a various embodiment, the one or more elongated protrusions and/or recesses have a cross-section when cut substantially rectangular to a direction of elongation, wherein the cross-section has the shape of a truncated cone, a pyramid, a rectangle, a trapeze, and/or combinations thereof.

The shape of a truncated cone, a pyramid, a rectangle, a trapeze, and/or combinations thereof has the advantage that a greater amount of radiated and/or reflected electromagnetic energy can be interfered. This facilitates to reduce noise and aids that for instance remaining electronic component(s) operate more reliably. As an example, their radio frequency may not be impaired, and any angular error may be reduced. An angular error may be induced if electromagnetic energy is imparted to an electronic component (e.g. a transmission line directed to an antenna), wherein the imparted electromagnetic energy has a different phase coding compared to the radio frequency of the electronic component. Accordingly, the shielding element improves to reduce any angular error.

In the shielding element as described herein, the one or more elongated protrusions and/or recesses have a height, respectively a depth of at least 0.2 mm, at least 0.4 mm, at least 0.6 mm, at least 0.8 mm, or at least 1.0 mm; at least one wherein the height, respectively the depth is at most 4 mm, at most 3 mm, at most 2 mm, at most 2.5 mm, or at most 1 mm.

The inventors found that the height (respectively depth) of the one or more elongated protrusions and/or recesses should be not too large and not too small. In various implementations, the term “height” can be used for simplicity to refer to the height of a protrusion or the depth of a recess.

The height (respectively depth) should be large such that a sufficient interference with the electromagnetic energy is ensured. However, the height (respectively depth) should not be too large, otherwise substantial further improvements may not be achieved but manufacturing costs could increase. Further, if the height (respectively depth) is too large, it might impair different components and or parts that are located in proximity to the shielding element (e.g. inside the shielding element).

Accordingly, the inventors found that an optimum balance should be struck for the height (respectively depth) to provide a compact shielding element, which facilitates sufficient improvement for noise reduction.

The height as used herein may be understood as the distance from a point of the one or more elongated protrusions and/or recesses that is furthest away from the inner wall seen along a straight line that is substantially perpendicular to the inner wall.

In the shielding element as described herein, the one or more elongated protrusions and/or recesses have a maximum width parallel to the inner wall of at least 0.2 mm, at least 0.4 mm, at least 0.6 mm, at least 0.8 mm, o at least 1.0 mm; and wherein the maximum width is at most 4 mm, at most 3 mm, at most 2 mm, at most 2.5 mm, or at most 1 mm.

The maximum width of the one or more elongated protrusions and/or recesses should be large such that a sufficient interference with the electromagnetic energy is ensured. However, the maximum width should not be too large, otherwise substantial further improvements may not be achieved but manufacturing costs could increase, which is not desired. Further, if the maximum width is too large, it might impair different components and or parts that a located in proximity to the shielding element (e.g. inside the shielding element).

Accordingly, an optimum balance should be struck for the maximum width to provide a compact shielding element, which facilitates sufficient improvement for noise reduction.

In the shielding element as described herein, the one or more elongated protrusions and/or recesses are distributed equidistantly on the inner wall.

The maximum width as used herein may be understood as the maximum width of a cross-section when cut substantially rectangular to a direction of elongation of the one or more elongated protrusions and/or recesses. If the cross-section has a tampered shaped, the maximum width may be arranged in near proximity to the inner wall.

In the shielding element as described herein, the one or more elongated protrusions and/or recesses are arranged in a curved and/or zig-zag shape on the inner wall.

This specified shape may be regarded as such a shape when seen from a frontal view of the inner wall. Thus, as an example, the zig-zag shape means that the one or more elongated protrusions and/or recesses alternate their direction substantially parallel to the inner wall by a consecutive arrangement of a substantial straight line and a substantial sharp corner.

This has the advantage that the interference with the electromagnetic energy can be controlled in a better way. I.e. it could be possible to manufacture a certain shape to specifically aim at a certain amount of isolation that the shielding element should provide. This may, in one example, depend on the electronic component(s) to be shielded.

In a various embodiment, in the shielding element as described herein, at least part of the structure is adapted to be arranged substantially opposite to and facing the electronic component(s) when assembled.

The structure being opposite to and facing the electronic component(s) has the advantage that the structure is arranged at a meaningful location of the inner wall. Thereby, it improves the interference with electromagnetic energy.

In one example, the structure could be adapted to be arranged solely opposite to and facing the electronic component(s). This may be desired in case only this electronic component(s) is to be shielded. Thus, material may not unnecessarily be wasted.

In a various embodiment, in the shielding element as described herein, the inner wall includes a thermal region arranged to be in thermal contact with the electronic component(s) when assembled.

The thermal region as used herein may be understood as a region that is able to act as a heat sink. Thus, heat produced by electronic component(s) can be advantageously absorbed. As an example, the thermal region may be provided as a recess (one could also say that it has the appearance of a dome), which could be larger than the previously described one or more elongated recesses of the structure. A thermal connection of the shielding element to the electronic component(s), such as an IC can thus be established by way of the thermal region. Accordingly, the IC may be cooled, when assembled.

In one example, the thermal region may be provided with a surface roughness, such as to improve a connection of a material applied on the thermal region. This material could be a thermal interface material.

It is appreciated that the surface roughness also improves interference with the electromagnetic energy. Thereby, a noise is advantageously reduced. In one example, the surface roughness could alternatively or additionally be provided on the structure. The surface roughness could be provided on the one or more elongated protrusions and/or recesses. In another example, the surface roughness could be provided solely on the inner wall at which substantially no structure is present (e.g. on the thermal region). Overall this improves to reduce a scattering of electromagnetic energy as described herein.

The surface roughness may be substantially smaller compared to the one or more elongated protrusions and/or recesses. The surface roughness may have a dimension, which is small than about 0.1 times a wavelength of the electromagnetic energy.

In an example, the one or more elongated protrusions and/or recess are not provided on the thermal region.

In the shielding element as described herein, at least part of the structure is integral with the shielding element and/or at least part of the structure is provided as a separate piece.

It is appreciated that the structure could be formed as substantially one piece with the inner wall and/or the shielding element. This significantly improves manufacturing costs. As an example, the structure could be manufactured by a stamping process. The provision as a separate piece has the advantage that more advanced shapes of the structure may be provided relatively simply.

In the shielding element as described herein, the shielding element does not include absorber material, wherein the absorber material is defined as a material adapted to attenuate electromagnetic energy of at least 10 dB/cm, at least 20° dB/cm, or at least 30° dB/cm at a frequency of the electromagnetic energy in the range from 2 GHz to 120 GHz, from 10 GHz to 100 GHz, from 40 GHz to 95 GHz, from 60 GHz to 90 GHz, from 70 GHz to 85 GHz, or from 76 GHz to 81 GHz, when measured by insertion loss on an absorber material thickness of 0.5 cm to 1.5 cm, or 0.9 cm to 1.1 cm.

This facilitates that cheaper material and in particular conventional materials may be used. As an example, a conductive material such as a metal could be applied. Thus, it is not necessarily required to apply expensive materials, such as Radio Frequency (RF) absorbing materials. Notably, the frequency band of 76 GHz to 81 GHz corresponds to the radar band, which may be applied in the context of the present disclosure.

In one example, the shielding element includes at least 80%, at least 90%, at least 95%, or at least 99% metal. The metal could be aluminum, in one example.

In the shielding element as described herein, the inner wall includes an inner top wall and at least four inner side walls substantially rectangular to the inner top wall. The inner wall forms a substantially hollow portion for at least partially housing the electronic component(s) when assembled. The structure is arranged on the inner top wall and not on the at least four inner side walls. The shielding element has an outer shape of a cuboid.

The shape of the cuboid could be such that a length and a width are substantially larger than a height of the cuboid. In this regard, the height could be the height seen in the direction of the top inner wall to the electronic component(s) when assembled.

A further aspect of the invention is directed to a system for a radar, the system including a shielding element according to any one of the preceding examples, electronic component(s), such as an integrated circuit (IC) or a transmission line, configured to radiate electromagnetic energy. The shielding element is arranged to at least partially shield electromagnetic energy radiating from the electronic component(s).

As an example, the system may further include a first antenna (being a transmitter (Tx) or a receiver (Rx)) and a second antenna (also being a transmitter (Tx) or a receiver (Rx)). Furthermore, the electronic component(s) may include an IC and a first transmission line leading to the first antenna and a second transmission line leading to the second antenna. In addition, there may be a different phase coding of the frequency of the first and the second transmission line. Electromagnetic energy may be radiated from the first transmission line and could adversely affect the second transmission line.

Accordingly, the shielding element of the system for a radar is configured to substantially shield (undesired) electromagnetic energy between the first antenna and the second antenna and/or between the first transmission line and the second transmission line.

In a various embodiment, in the system for a radar, the shielding element is adapted to have an isolation of at least 35 dB, at least 37 dB, at least 39 dB, at least 41 dB, or at least 42 dB, optionally when measured at a frequency of 76.5 GHz.

It may also be possible to achieve the isolation values at a frequency in the range from about 76 GHz to about 81 GHz. This could be the range in which a radar operates (it could also be 76 GHz to 77 GHz).

In one example, there may be an isolation domain with respect to a radar between transmitter (Tx) and receiver (Rx) transmission (or feeding) lines. This domain may demand high isolation. It is appreciated that isolation values of at least 40 dB can be reached.

In another example, there may be an isolation domain with respect to a radar between Rx and Rx transmission lines, and/or between Tx and Tx transmission lines. This domain may not demand such a high isolation. Typically, providing an isolation is difficult, because a distance between Rx and Rx ports and/or between Tx and Tx ports is usually very small.

A particular contribution of the present disclosure is that the aspects described herein are not limited to dedicated shielding elements, but could be applied to substantially any elements that enclose, cover and/or are in vicinity to electronic structures and feeding lines.

It is noted that the features, aspects, embodiments and/or advantages as described herein with reference to the shielding element may likewise be applicable to the system for a radar, even if not expressly described as such but rather with reference to features, aspects, embodiments and/or advantages of the shielding element. It is also to be understood that features, aspects, embodiments and/or advantages described with reference to the system for a radar may equally be applicable to the shielding element.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 illustrates an example shielding element for electronic components according to the prior art in a side cross-sectional view.

FIG. 2 illustrates the example shielding element for electronic components according to the prior art of FIG. 1 in a perspective view.

FIG. 3 illustrates a shielding element for electronic components according to an embodiment of the invention in a side cross-sectional view.

FIG. 4 illustrates a shielding element for electronic components according to an embodiment of the invention in a perspective view.

FIG. 5 illustrates a shielding element for electronic components according to a further embodiment of the invention in a perspective view.

FIG. 6 illustrates a shielding element for electronic components according to a further embodiment of the invention in a perspective view.

FIG. 7 illustrates a shielding element for electronic components according to a further embodiment of the invention in a perspective view.

FIG. 8 illustrates a shielding element for electronic components with a thermal region according to a further embodiment of the invention in a perspective view.

FIG. 9 illustrates example dimensions of protrusions and recesses included by the structure of the inner wall of the shielding element according to embodiments of the invention in a side cross-sectional view.

In the drawings, reference numbers may be reused to identify similar and/or identical elements.

### DETAILED DESCRIPTION

The term Electromagnetic Interference (EMI) may also be termed radio-frequency interference (RFI) when applicable to the radio frequency spectrum. The EMI is a disturbance generated by, e.g. an external source, that affects an electrical circuit and/or an electronic component by electromagnetic induction, electrostatic coupling, or conduction. The disturbance may degrade the performance of the electrical circuit and/or an electronic component or even stop it from functioning properly.

As used herein, the “noise” may also be understood as coupling path(s), energy transfer line(s) or the like, which adversely affect a desired radio wave to be transmitted, e.g. a radio wave transmitted via one or more transmission lines. Thus, a desired transmission of electromagnetic energy may be impaired by way of the noise.

A “radio wave” is inherently coupled to its radio frequency, as an example, at a (radio) frequency of 300 GHz, the corresponding wavelength (e.g. the length of the radio wave) is 1 mm. At a (radio) frequency of 30 Hz the corresponding wavelength is 10,000 kilometers.

In the subsequent passages, the invention is described with reference to the accompanying figures in more detail. It is noted that further embodiments are certainly possible, and the below explanations are provided by way of example only, without limitation.

While specific feature combinations are described in the following with respect to the example embodiments of the present invention, it is to be understood that not all features of the discussed embodiments have to be present for realizing the invention, which is defined by the subject matter of the claims. The disclosed embodiments may be modified by combining certain features of one embodiment with one or more features of another embodiment. Specifically, the skilled person will understand that features, components and/or functional elements of one embodiment can be combined with technically compatible features, components and/or functional elements of any other embodiment of the present invention given that the resulting combination falls within the definition of the invention provided by the claims. The skilled person also understands that certain features may be omitted in so far as they appear dispensable.

Throughout the present figures and specification, the same reference numerals refer to the same elements. The figures may not be to scale, and the relative size, proportions, and depiction of elements in the figures may be exaggerated for clarity, illustration, and convenience.

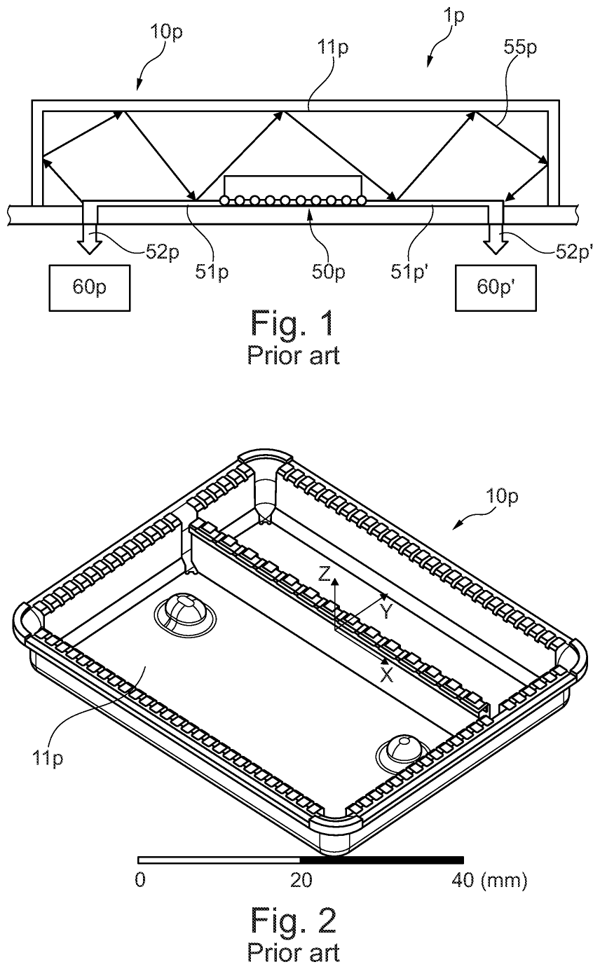

FIG. 1 shows an example shielding element 10p for electronic components 50p, 51p, 51p′, 52p, 52p′ according to the prior art. Particularly a system for a radar 1p according to the prior art is shown. The shielding element 10p is facing an integrated circuit (IC) 50p.

A first transmission line 51p and a second transmission line 51p′ are shown that pass through a first transition 52p and a second transition 52p′, respectively. The first transmission line 51p and the second transmission line 51p′ lead to a first antenna 60p and a second antenna 60p′ for providing energy, such as electromagnetic energy in the regime of a radio frequency.

The shielding element 10p has an inner wall 11p that is facing the IC 50p, the first transmission line 51p, the second transmission line 51p′, the first transition 52p and the second transition 52p′. The shielding element 10p and/or the inner wall 11p are of metal material, which is a conductive material. The inner wall 11p is flat, which facilitates reflection of the energy transfer as indicated by lines 55p.

FIG. 1 further indicates that the energy transfer line 55p is radiated from the IC 50p and/or the transmission lines 51p, 51p′ and is reflected several times due to the shielding element 10p, particularly by the inner wall 11p of the shielding element 10p.

This depicted conventional shielding element 10p having such an arrangement of a flat inner wall 11p and a conductive material leads to substantial noise of the system and adversely affects the radar's accuracy of the detection and/or tracking of objects. This is caused by the radiated/reflected electromagnetic energy, as indicate by i.e. the energy transfer line 55p, which influences the different antennas 60p, 60p′. Accordingly, the conventional shielding element 10p leads to a reduced performance of the system for a radar 1p.

FIG. 2 shows the example shielding element 10p according to the prior art of FIG. 1 in a perspective view. It can be seen that the inner wall 11p is substantially flat, which is disadvantageous as described herein.

The shielding element 10p according to the prior art of FIGS. 1 and 2 do not reveal a sufficient isolation. As an example, the isolation would be at most 34 dB at a frequency of 76.5 GHz, which is not sufficient.

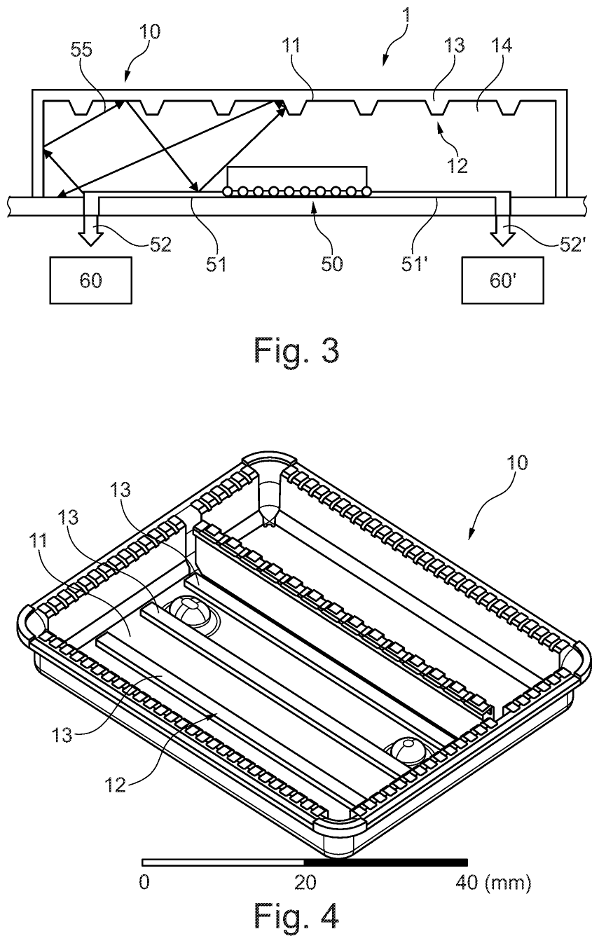

FIG. 3 shows a shielding element 10 for electronic components 50, 51, 51′, 52, 52′ according to an embodiment of the invention in a side cross-sectional view.

The description of the reference numerals of FIG. 1 applies in here as well for the reference numerals without the addition of “p”. Thus, as an example, the IC 50p of FIG. 1 is similar to the IC of 50 of this figure. Thus, part of the description is left for brevity in here.

Some of the differences to FIG. 1 are explicitly described herein.

The inner wall 11 is adapted to face the electronic component(s) 50, 51, 51′, 52, 52′ when assembled. The inner wall 11 includes a material for at least partially reflecting the electromagnetic energy radiated by the electronic component(s) 50, 51, 51′, 52, 52′.

The inner wall 11 includes a structure 12, adapted to interfere with the radiated and/or reflected electromagnetic energy 55. The radiated and/or reflected electromagnetic energy 55 is indicated by the energy transfer line 55.

The radiated and/or reflected electromagnetic energy 55 is prevented from scattering further, e.g. scattering towards another electronic component 50, 51, 51′, 52, 52′, in particular towards the second transmission line 51′ and/or the second transition 52′. Thus, the radio frequency that the second transmission line 51′ transmits to the second antenna 60′ is not impaired, which is attributable to the structure 12 that interferes with the radiated and/or reflected electromagnetic energy 55.

The structure includes one or more elongated protrusions 13, only one of which is indicated in this figure. Additionally, it may also be possible that the spaces between the one or more protrusions 13 are regarded as one or more elongated recesses 14 (only one of which is indicated).

FIG. 4 shows a shielding element 10 for electronic components according to an embodiment of the invention in a perspective view. The shielding element has an inner wall 11 including a structure 12. The structure has three elongated protrusions 13.

The protrusions 13 have the shape of ridges. Furthermore, the protrusions 13 have a cross-section when cut substantially rectangular to a direction of elongation, wherein the cross-section has the shape of a truncated cone, but it could also be a pyramid, a rectangle, a trapeze etc. This can also be seen in FIG. 3, showing the cross-section more clearly.

The isolation of this shielding element 10 is improved over the shielding element 10p according to the prior art of FIGS. 1 and 2. The embodiment of this figure shows an isolation of about at least 39 dB at a frequency of 76.5 GHz, which corresponds to an improvement of about 5 dB.

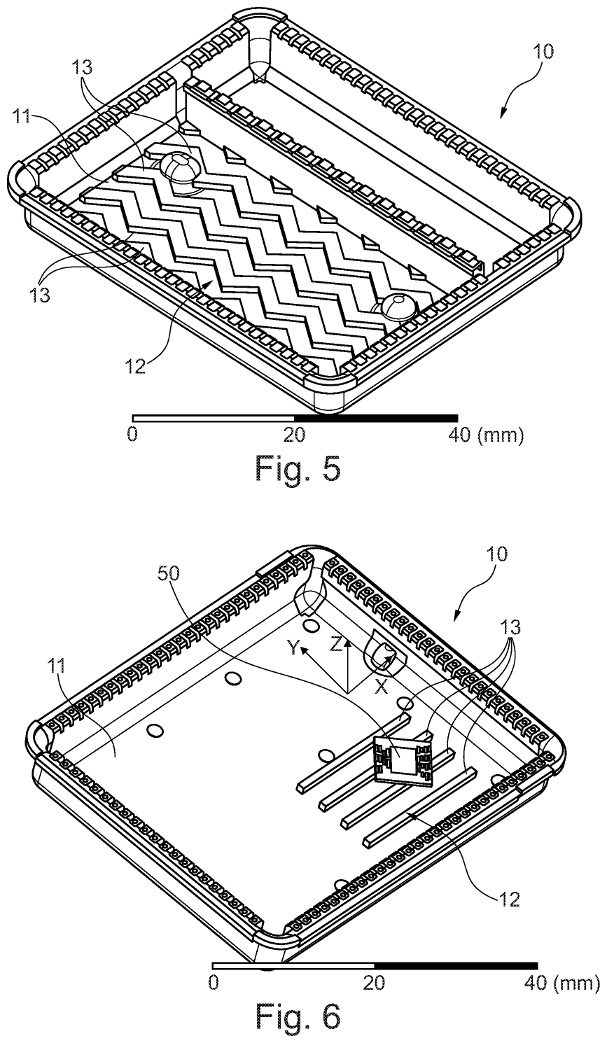

FIG. 5 shows a shielding element 10 for electronic components according to a further embodiment of the invention in a perspective view.

The shielding element 10 is similar to the one of the preceding embodiments. The one or more elongated protrusions 13 are arranged in a zig-zag shape on the inner wall 11. In this Figure, about five protrusions 13 are shown. However, the fifth protrusion is merely indicated in an upper region of this figure.

In this figure, the structure 12 covers a greater extent of the surface of the inner wall 11 compared to the embodiment of FIG. 4.

The isolation of this shielding element 10 is improved over the shielding element 10p according to the prior art of FIGS. 1 and 2. The embodiment of this figure shows an isolation of about at least 41 dB to 42 dB at a frequency of 76.5 GHz, which corresponds to an improvement of about 6 dB to 7 dB.

FIG. 6 shows a shielding element 10 for electronic components 50 according to a further embodiment of the invention in a perspective view. An IC 50 is also indicated.

The structure 12 is similar to the one of the embodiments of FIG. 4, however, four elongated protrusions 13 are now shown as opposed to three. At least part of the structure 12 is adapted to be arranged substantially opposite to and facing the electronic component 50 when assembled.

In particular, the elongated protrusions 13 are arranged substantially in proximity to the IC. The remainder of the inner wall 11 does not necessarily have to have the structure 12 as an interference with radiated and/or reflected electromagnetic energy may not be necessary in this area.

It may be possible that, in various implementations, distance from the structure 12 to the electronic component 50 when assembled is at most 15 mm, or at most 10° mm, or at most 8 mm, or at most 5 mm. This could enhance interference with the radiated and/or reflected electromagnetic energy. It may be the case that a lower end limitation of the distance from the structure 12 to the electronic component may be given by mechanical limitations. Such as mechanical limitations due to the stamping process, if the stamping process is applied for providing the structure. It was found that in one example, spacings of about 3 mm show good isolation values.

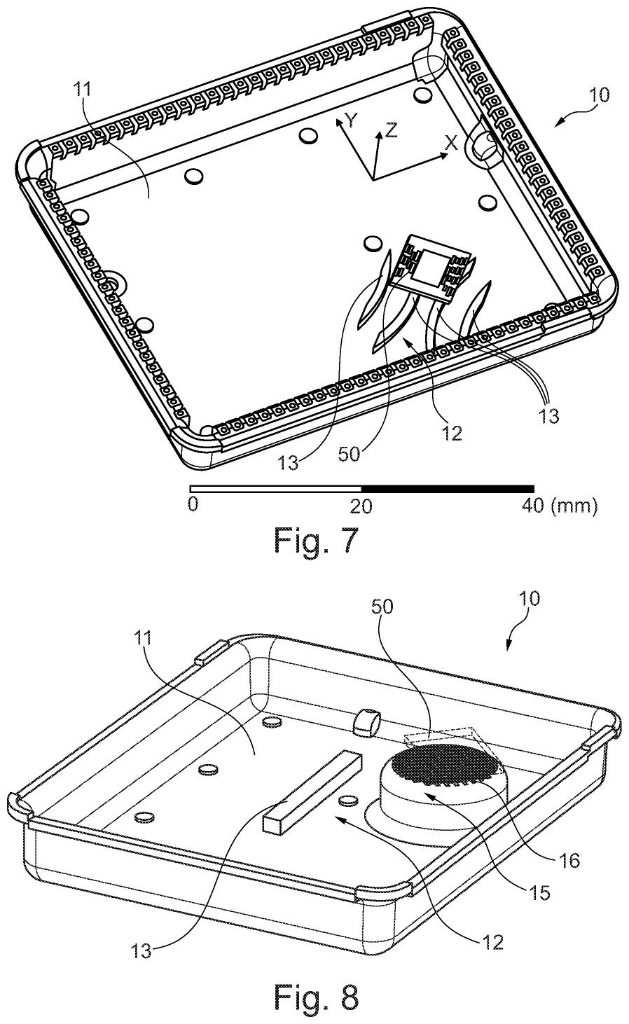

FIG. 7 shows a shielding element 10 for electronic components 50 according to a further embodiment of the invention in a perspective view.

The shielding element 10 is similar to the one of FIG. 6. The difference to the embodiment of FIG. 6 is that the one or more elongated protrusions 13 are arranged in a curved shape on the inner wall 11. Also, four elongated protrusions 13 are shown. At least part of the structure 12 is adapted to be arranged substantially opposite to and facing the electronic component 50 when assembled (as mentioned in the context of the embodiment of FIG. 6).

The following description may not be particularly limited to the embodiment of FIG. 7 as understood by the skilled person: the inner wall 11 includes an inner top wall and at least four inner side walls substantially rectangular to the inner top wall. The inner wall 11 forms a substantially hollow portion for at least partially housing the electronic component(s) 50 when assembled. The structure 12 is arranged on the inner top wall and in various implementations not on the at least four inner side walls. The shielding element 10 has an outer shape of a cuboid.

The shape of the cuboid could be such that a length and a width are substantially larger than a height of the cuboid. An example length could be about 60 mm. An example width could be about 40 mm. An example height could be about 5 mm to 10 mm.

FIG. 8 shows a shielding element 10 for electronic components 50 with a thermal region 15 according to a further embodiment of the invention in a perspective view.

Similar to the preceding embodiments, the shielding element 10 includes an inner wall 11 including a structure 12. For example, one elongated protrusion 13 is indicated.

The inner wall 11 also includes a thermal region 15 arranged to be in thermal contact with the electronic component 50 when assembled. The thermal region 15 can act as a heat sink. Thus, heat produced by electronic component 50 can be absorbed. The thermal region 15 is provided as a dome. A thermal connection of the shielding element 10 to the electronic component 50 can thus be established by way of the thermal region 15 and the electronic can be cooled, when assembled.

The thermal region 15 is be provided with a surface roughness 16, to improve a connection of a material applied on the thermal region 15. This material could be a thermal interface material.

The surface roughness 16 could alternatively or additionally be provided on the structure 12. The surface roughness 16 could be provided on the one or more elongated protrusions 13 and/or recesses 14.

It is understood that the surface roughness 16 is substantially smaller than the one or more elongated protrusions.

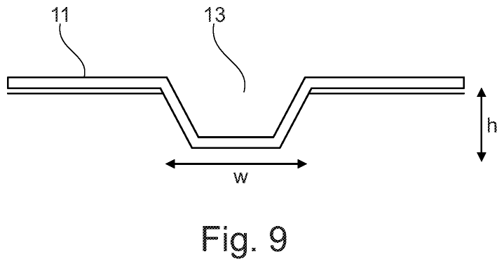

FIG. 9 shows example dimensions of protrusions 13 included by the structure 12 of the inner wall 11 of the shielding element 10 according to embodiments of the invention in a side cross-sectional view.

This should support the understanding of the height, respectively the depth of the one or more elongated protrusions 13 and/or recesses 14 as used herein.

The height (depth) is indicated as “h” and is the distance from a point of the one or more elongated protrusions 13 that is furthest away from the inner wall 11 seen along a straight line that is substantially perpendicular to the inner wall 11.

The maximum width is indicated as “w” and is the maximum width of a cross-section when cut substantially rectangular to a direction of elongation of the one or more elongated protrusions 13, as shown in this figure. These observations apply analogously to recesses.

It is noted that in the above embodiments, the integrated circuit (IC) could be a Monolithic microwave integrated circuit (MMIC). A MMIC is a type of IC that operates at microwave frequencies (e.g. 300 MHz to 300 GHz). MMICs typically perform functions such as microwave mixing, power amplification, low-noise amplification, and high-frequency switching.

It is also noted that the shielding element may include first shielding layer and a second shielding layer. The inner wall could be part of the first shielding layer. In one example, the first shielding layer has a thickness of at least 0.2 mm, at least 0.4 mm, at least 0.6 mm, at least 0.8 mm, or at least 1.0 mm; and/or the first shielding layer has a thickness of at most 10 mm, at most 6 mm, at most 3 mm, at most 2 mm, or at most 1 mm. Accordingly, the inner wall could have a similar thickness. This has the advantage that the thickness of the inner wall/first shielding layer is sufficient such that the structure can be easily provided to the inner wall.

In a further example the thickness of the second shielding layer is at least 0.01 mm, at least 0.02 mm, at least 0.05 mm, at least 0.08 mm, at least 0.1 mm; and/or the thickness of the second shielding layer is at most 0.8 mm, at most 0.5 mm, at most 0.2 mm, at most 0.15 mm, or at most 0.1 mm.

Accordingly, the second shielding layer of the shielding element is thinner than the first shielding layer. As an example, the second (thinner) shielding layer is arranged closer to an electronic component when assembled, wherein the second shielding layer has one or more cutouts, such that the structure of the inner wall of the first shielding layer of the shielding element can be easily reached by radiated and/or reflected electromagnetic energy. In case the structure includes protrusions, the protrusions would protrude through the cutouts.

This facilitates a simplified manufacturing process of the two shielding layers. For instance, the structure could be provided to the first shielding layer, which is thick enough to substantially not break when the structure is provided. As an example, the structure could be provided by a stamping process, which is a cost-effective manufacturing process.

In another example, the structure may be provided by a molding process, e.g. the shielding could be manufacturing by casting in a mold. In such a case, it is appreciated that substantially no mechanical limitations with regard to materials' thicknesses needs to be taken into consideration.

In all of the embodiments described in the figures, at least part of the structure 12 is integral with the shielding element 10 and/or at least part of the structure 12 is provided as a separate piece, i.e. as a separate piece to the shielding element 10.

It will be apparent to those skilled in the art that numerous modifications and variations of the described examples and embodiments are possible in light of the above teaching. The disclosed examples and embodiments are presented for purposes of illustration only. Other alternate embodiments may include some or all of the features disclosed herein. Therefore, it is the intent to cover all such modifications and alternate embodiments as may come within the true scope of this invention. The scope of protection is determined by the claims and is not limited by the embodiments disclosed in the above figures.

The term non-transitory computer-readable medium does not encompass transitory electrical or electromagnetic signals propagating through a medium (such as on a carrier wave). Non-limiting examples of a non-transitory computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The phrase “at least one of A, B, and C” should be construed to mean a logical (A OR B OR C), using a non-exclusive logical OR, and should not be construed to mean “at least one of A, at least one of B, and at least one of C.” The phrase “at least one of A, B, or C” should be construed to mean a logical (A OR B OR C), using a non-exclusive logical OR.

### LIST OF REFERENCE SIGNS

1p prior art: system for a radar
10p prior art: shielding element for electronic component(s)
11p prior art: inner wall
50p prior art: integrated circuit
51p prior art: first transmission line
51p′ prior art: second transmission line
52p prior art: first transition
52p′ prior art: second transition
55p prior art: radiated and/or reflected electromagnetic energy, energy transfer line
60p prior art: first antenna
60p′ prior art: second antenna
1 system for a radar
10 shielding element for electronic component(s)
11 inner wall
12 structure
13 one or more protrusions
14 one or more recesses
thermal region
16 surface roughness
50 integrated circuit
51 first transmission line
51′ second transmission line
52 first transition
52′ second transition
55 radiated and/or reflected electromagnetic energy, energy transfer line
60 first antenna
60′ second antenna
w maximum width of the one or more elongated protrusions and/or recesses
h height/depth of the one or more elongated protrusions and/or recesses

1. A shielding element for at least partially shielding electromagnetic energy radiating from an electronic component, the shielding element comprising:
an inner wall adapted to face the electronic component when assembled,
wherein the inner wall includes a material configured to at least partially reflect the electromagnetic energy radiating from the electronic component, and
wherein the inner wall includes a structure adapted to interfere with at least one of the radiated or reflected electromagnetic energy.

2. The shielding element of claim 1 wherein the structure covers at least 10% of a surface of the inner wall.

3. The shielding element of claim 1 wherein the structure covers at least 50% of a surface of the inner wall.

4. The shielding element of claim 1 wherein:
the structure includes one or more elongated protrusions or recesses; and
the one or more elongated protrusions or recesses have a ridge shape.

5. The shielding element of claim 4 wherein:
the one or more elongated protrusions or recesses have a cross-section when cut substantially rectangular to a direction of elongation; and
the cross-section has a shape based on at least one of a truncated cone, a pyramid, a rectangle, or a trapezoid.

6. The shielding element of claim 4 wherein the one or more elongated protrusions or recesses have a height in a range of 0.2 mm to 4 mm.

7. The shielding element of claim 4 wherein the one or more elongated protrusions or recesses have a height in a range of 1.0 mm to 2 mm.

8. The shielding element of claim 4 wherein the one or more elongated protrusions or recesses have a maximum width parallel to the inner wall in a range of 0.2 mm to 4 mm.

9. The shielding element of claim 4 wherein the one or more elongated protrusions or recesses have a maximum width parallel to the inner wall in a range of 1.0 mm to 2 mm.

10. The shielding element of claim 4 wherein the one or more elongated protrusions or recesses are distributed equidistantly on the inner wall.

11. The shielding element of claim 4 wherein the one or more elongated protrusions or recesses are arranged on the inner wall in at least one of a curved shape or a zig-zag shape.

12. The shielding element of claim 1 wherein at least part of the structure is adapted to be arranged substantially opposite to and facing the electronic component when assembled.

13. The shielding element of claim 1 wherein the inner wall includes a thermal region arranged to be in thermal contact with the electronic component when assembled.

14. The shielding element of claim 1 wherein at least part of the structure is integral with the shielding element.

15. The shielding element of claim 1 wherein at least part of the structure is provided as a separate piece.

16. The shielding element of claim 1 wherein:
the shielding element does not include absorber material; and
the absorber material is defined as a material adapted to attenuate electromagnetic energy of at least 10 dB/cm at a frequency of the electromagnetic energy in a range from 2 GHz to 120 GHz, when measured by insertion loss on an absorber material thickness of 0.5 cm to 1.5 cm.

17. The shielding element of claim 1 wherein:
the shielding element does not include absorber material; and
the absorber material is defined as a material adapted to attenuate electromagnetic energy of at least 30° dB/cm at a frequency of the electromagnetic energy in a range from 76 GHz to 81 GHz, when measured by insertion loss on an absorber material thickness of 0.9 cm to 1.1 cm.

18. The shielding element of claim 1 wherein:
the inner wall includes an inner top wall and at least four inner side walls substantially rectangular to the inner top wall;
the inner wall forms a substantially hollow portion for at least partially housing the electronic component when assembled;
the structure is arranged on the inner top wall and not on the at least four inner side walls; and
the shielding element has an outer shape of a cuboid.

19. A system for a radar, the system comprising:
the shielding element of claim 1; and
the electronic component.

20. The system of claim 19 wherein the electronic component is at least one of an integrated circuit (IC) or a transmission line.

21. The system of claim 19 wherein the shielding element is adapted to have an isolation of at least 35 dB.

22. The system of claim 19 wherein the shielding element is adapted to have an isolation of at least 42 dB when measured at a frequency of 76.5 GHz.
